(19) United States
(12) Patent Application Publication
(10) Pub. No.: US 2018/0356722 A1
(43) Pub. Date: Dec. 13, 2018

(54) COLORED PHOTOSENSITIVE RESIN COMPOSITION AND LIGHT SHIELDING SPACER PREPARED THEREFROM

(71) Applicant: Rohm and Haas Electronic Materials Korea Ltd., Cheonan (KR)

(72) Inventors: Kyung-Jae Park, Hwaseong (KR); Hyung-Tak Jeon, Hwaseong (KR); Ji Ung Kim, Hwaseong (KR); Jong-Ho Na, Hwaseong (KR); Hyung Gu Kim, Seo-gu (KR)

(21) Appl. No.: 15/993,645

(22) Filed: May 31, 2018

(30) Foreign Application Priority Data
Jun. 12, 2017 (KR) 10-2017-0073410

(51) Int. Cl. G03F 7/00; G03F 7/031; G03F 7/033; G02F 1/1339

(52) U.S. Cl. CPC G03F 7/0007; G03F 7/031; H01L 27/3272; G02F 1/13394; G02F 2001/13398; G03F 7/033

(57) ABSTRACT

The present invention relates to a colored photosensitive resin composition and to a light shielding spacer produced therefrom. The colored photosensitive resin composition comprises epoxy groups and double bonds in a specific molar ratio and an oxime ester fluorene-based photopolymerization initiator in a smaller amount than a conventional oxime ester-based photopolymerization initiator, so that it has excellent photo-curing characteristics. As a result, it is possible to improve the high sensitivity characteristics such as resolution and step difference even with a small amount of light. Specifically, since the curing characteristics of the film surface is improved, it is to possible to reduce the generation of outgassing, which is a contamination source that may be generated when the film is dried. In addition, the colored photosensitive resin composition is capable of forming a cured film that minimizes the generation of uneven wrinkles on its surface. Accordingly, the colored photosensitive resin composition can be advantageously used as a material for forming a light shielding spacer such as a black column spacer to be employed in various electronic parts inclusive of a liquid crystal display (LCD) panel and an organic light emitting diode (OLED) display panel.

### TECHNICAL FIELD

The present invention relates to a colored photosensitive resin composition that is capable of reducing the generation of outgassing, which is a contamination source, during the manufacturing process; is excellent in such properties as sensitivity, elastic recovery rate, resolution, resistance to exudation, formation of a step difference, and the like; and is capable of forming a cured film that minimizes the generation of uneven wrinkles on its surface, and to a light shielding spacer produced therefrom which is used for a liquid crystal display, an organic EL display, and the like.

### BACKGROUND ART

Recently, a spacer prepared from a photosensitive resin composition is employed in order to maintain a constant distance between the upper and lower transparent substrates in liquid crystal cells of a liquid crystal display (LCD). In an LCD, which is an electro-optical device driven by a voltage applied to a liquid crystal material injected into a constant gap between two transparent substrates, it is very critical to maintain the gap between the two substrates to be constant. If there is an area in which the gap between the transparent substrates is not constant, the voltage applied thereto as well as the transmittance of light penetrating this area may vary, resulting in a defect of spatially non-uniform luminance. According to a recent demand for large LCD panels, it is even more critical to maintain a constant gap between two transparent substrates in an LCD.

Such a spacer may be prepared by coating a photosensitive resin composition onto a substrate and exposing the coated substrate to ultraviolet rays and so on with a mask placed thereon, followed by development thereof. Recently, efforts of using a light shielding material for a spacer have been made; accordingly, various colored photosensitive resin compositions have been actively developed.

In recent years, a black column spacer (BCS) in which a column spacer and a black matrix are integrated into a single module using a colored photosensitive resin composition has been aimed to simplify the process steps. The colored photosensitive resin composition used in the production of such a black column spacer is required to easily form a step difference and to meet excellent sensitivity and an elastic recovery rate at the same time to have resistance to the pressure of the upper plate.

Meanwhile, if a cured film has uneven wrinkles on its surface when a bezel is formed from a colored photosensitive resin composition in a display panel, it may cause a serious disadvantage that the amount of injected liquid crystals may not be uniform due to a defect in the gap between the upper and lower plates during their assembly or that spots may be generated on the display screen due to a poor transmission of electric signals.

In order to resolve this problem, Korean Patent No. 1291480 discloses a photosensitive resin composition that comprises an acrylic resin (or a binder) for the purpose of suppressing the generation of wrinkles. In the case of this patent, however, since the acrylic resin thus employed comprises (meth)acrylic acid units in a large amount of 60 to 85% by mole, there exists a disadvantage that it is difficult to form a step difference of a pattern at the time of producing a light shielding spacer due to such a high acid value of the acrylic resin.

Meanwhile, since a colored photosensitive resin composition for a light shielding spacer must comprise a coloring pigment in order to materialize the light shielding property, the degree of photo-curing is relatively deficient to that of a transparent spacer. If the degree of photo-curing of the film surface is insufficient, the impurities contained in the colored photosensitive resin composition can be easily released through the film surface during the post-bake process in which the cured film is finally dried after the light exposure and development processes, thereby generating a large amount of a contamination source called outgassing. The outgassing may cause such problems as contamination of equipment in the post-processing.

### PRIOR ART DOCUMENT

### Patent Document

(Patent Document 1) Korean Patent No. 1291480

### DISCLOSURE OF INVENTION

### Technical Problem

Accordingly, an object of the present invention is to provide a colored photosensitive resin composition that suppress the generation of uneven wrinkles on the surface of a cured film; is excellent in such properties as sensitivity, elastic recovery rate, resolution, resistance to exudation, formation of a step difference, and the like; and reduces the generation of outgassing, which is a contamination source, during the manufacturing process, and a light shielding spacer produced therefrom.

### Solution to Problem

In order to accomplish the above object, the present invention provides a colored photosensitive resin composition, which comprises (A) a copolymer comprising an epoxy group; (B) a photopolymerizable compound comprising a double bond; (C) a photopolymerization initiator; and (D) a colorant,

wherein the molar ratio of the double bonds in the photopolymerizable compound (B) to the epoxy groups in the copolymer (A) satisfies the following relationship:

4≤number of moles of double bonds/number of moles of epoxy groups≤35; and

the photopolymerization initiator (C) comprises an oxime ester fluorene-based initiator of the following Formula 1:

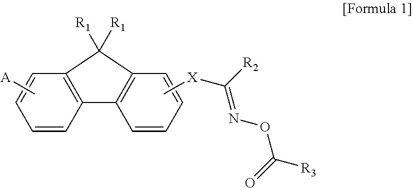

In Formula 1 above, R₁ is each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, or C₁₋₂₀ hydroxyalkoxyalkyl,

R₂ and R₃ are each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, C₁₋₂₀ hydroxyalkoxyalkyl, or C₄₋₂₀ heterocycle,

X is a single bond or carbonyl,

A is hydrogen, C₁₋₂₀ alkyl, C₆₋₃₀ aryl, C₁₋₂₀ alkoxy, C₇₋₃₀ arylalkyl, C₁₋₂₀ hydroxyalkyl, C₁₋₂₀ hydroxyalkoxyalkyl, C₃₋₂₀ cycloalkyl, amino, hydroxy, nitro, cyano, or

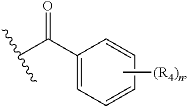

R₄ is R₅, OR₅, SR₅, COR₅, CONR₅R₅, NR₅COR₅, OCOR₅, COOR₅, SCOR₅, OCSR₅, COSR₅, CSOR₅, CN, halogen, or hydroxy,

R₅ is each independently C₁₋₂₀ alkyl, C₆₋₃₀ aryl, C₇₋₃₀ arylalkyl, or C₄₋₂₀ heterocycle,

n is an integer of 0 to 4.

In order to accomplish another object, the present invention provides a light shielding spacer produced from the colored photosensitive resin composition.

### Advantageous Effects of Invention

The colored photosensitive resin composition of the present invention comprises epoxy groups and double bonds in a specific molar ratio and an oxime ester fluorene-based photopolymerization initiator in a smaller amount than a conventional oxime ester-based photopolymerization initiator, so that it has excellent photo-curing characteristics. As a result, it is possible to improve the high sensitivity characteristics such as resolution and formation of a step difference even with a small amount of light. Specifically, since the curing characteristics of the film surface is improved, it is possible to reduce the generation of outgassing, which is a contamination source that may be generated when the film is dried. In addition, the colored photosensitive resin composition is capable of forming a cured film that minimizes the generation of uneven wrinkles on its surface. Accordingly, the colored photosensitive resin composition can be advantageously used as a material for forming a light shielding spacer such as a black column spacer to be employed in various electronic parts inclusive of a liquid crystal display (LCD) panel and an organic light emitting diode (OLED) display panel.

### BRIEF DESCRIPTION OF THE DRAWINGS

FIG. 1 is a schematic diagram of an embodiment of the cross-section of a light shielding spacer (or a black column spacer).

FIG. 2 is a photograph of the surfaces of the cured films formed from the compositions of Examples and Comparative Examples in order to evaluate the surface characteristics thereof.

FIG. 3 is a photograph of the light shielding spacers formed from the compositions of Examples and Comparative Examples taken in the thickness direction in order to evaluate the formation of a step difference therein.

### BEST MODE FOR CARRYING OUT THE INVENTION

The colored photosensitive resin composition of the present invention comprises (A) a copolymer comprising an epoxy group, (B) a photopolymerizable compound comprising a double bond, (C) a photopolymerization initiator, and (D) a colorant, and may further comprise (E) a compound derived from an epoxy resin and having a double bond, (F) an epoxy compound, (G) a surfactant, and/or (H) a solvent, if desired.

In the present disclosure, “(meth)acryl” means “acryl” and/or “methacryl,” and “(meth)acrylate” means “acrylate” and/or “methacrylate.”

Hereinafter, each component of the colored photosensitive resin composition will be explained in detail.

(A) Copolymer Comprising an Epoxy Group

The copolymer employed in the present invention comprises (a-1) a structural unit derived from an ethylenically unsaturated carboxylic acid, an ethylenically unsaturated carboxylic anhydride, or a combination thereof, (a-2) a structural unit derived from an ethylenically unsaturated compound containing an aromatic ring, and (a-3) a structural unit derived from an ethylenically unsaturated compound containing an epoxy group, and may further comprise (a-4) a structural unit derived from an ethylenically unsaturated compound different from the structural units (a-1), (a-2), and (a-3).

The copolymer is an alkali-soluble resin for materializing developability and also plays the role of a base for forming a film upon coating and a structure for forming a final pattern.

(a-1) Structural Unit Derived from an Ethylenically Unsaturated Carboxylic Acid, an Ethylenically Unsaturated Carboxylic Anhydride, or a Combination Thereof

The structural unit (a-1) is derived from an ethylenically unsaturated carboxylic acid, an ethylenically unsaturated carboxylic anhydride, or a combination thereof. The ethylenically unsaturated carboxylic acid and the ethylenically unsaturated carboxylic anhydride is a polymerizable unsaturated monomer containing at least one carboxyl group in the molecule. Particular examples thereof may include an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid of trivalence or more and an anhydride thereof; and a mono[(meth)acryloyloxyalkyl] ester of a polycarboxylic acid of divalence or more such as mono[2-(meth)acryloyloxyethyl]succinate, mono[2-(meth)acryloyloxyethyl] phthalate, and the like.

The structural unit derived from the above exemplified compounds may be comprised in the copolymer alone or in combination of two or more.

The amount of the structural unit (a-1) may be 5 to 65% by mole, preferably 10 to 50% by mole, based on the total moles of the structural units constituting the copolymer. Within the above amount range, the developability may be favorable.

(a-2) Structural Unit Derived from an Ethylenically Unsaturated Compound Containing an Aromatic Ring

The structural unit (a-2) is derived from an ethylenically unsaturated compound containing an aromatic ring. Particular examples of the ethylenically unsaturated compound containing an aromatic ring may include phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate; styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; 4-hydroxystyrene, p-hydroxy-α-methylstyrene, acetylstyrene; and vinyltoluene, divinylbenzene, vinylphenol, o-vinylbenzyl methyl ether, m-vinylbenzyl methyl ether, p-vinylbenzyl methyl ether, o-vinylbenzyl glycidyl ether, m-vinylbenzyl glycidyl ether, p-vinylbenzyl glycidyl ether, and the like.

The structural unit derived from the above exemplified compounds may be comprised in the copolymer alone or in combination of two or more. A structural unit derived from the styrene-based compounds among the above compounds is preferable in consideration of polymerizability.

The amount of the structural unit (a-2) may be 2 to 70% by mole, preferably 3 to 60% by mole, based on the total moles of the structural units constituting the copolymer. Within the above amount range, the copolymerizability and the resistance to development may be more favorable.

(a-3) Structural Unit Derived from an Ethylenically Unsaturated Compound Containing an Epoxy Group

The structural unit (a-3) is derived from an ethylenically unsaturated compound containing an epoxy group. Particular examples of the ethylenically unsaturated compound containing an epoxy group may include glycidyl (meth)acrylate, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, 4-hydroxybutyl (meth)acrylate glycidyl ether, 4-hydroxybutyl acrylate glycidyl ether, allyl glycidyl ether, 2-methylallyl glycidyl ether, and the like.

The structural unit derived from the above exemplified compounds may be comprised in the copolymer alone or in combination of two or more. A structural unit derived from glycidyl (meth)acrylate and/or 4-hydroxybutyl (meth)acrylate glycidyl ether among the above is more preferable in view of improvements in the elastic recovery rate and the sensitivity by virtue of the excellent degree of thermal curing.

The amount of the structural unit (a-3) may be 1 to 40% by mole, or 5 to 20% by mole, based on the total moles of the structural units constituting the copolymer. Within the above amount range, the residues during the process and the margins at the time of pre-bake may be more favorable.

(a-4) Structural Unit Derived from an Ethylenically Unsaturated Compound Different from the Structural Units (a-1), (a-2), and (a-3)

The copolymer employed in the present invention may further comprise a structural unit derived from an ethylenically unsaturated compound different from the structural units (a-1), (a-2), and (a-3) in addition to the structural units (a-1), (a-2), and (a-3).

Particular examples of the structural unit derived from an ethylenically unsaturated compound different from the structural units (a-1), (a-2), and (a-3) may include an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like.

The structural unit derived from the above exemplified compounds may be comprised in the copolymer alone or in combination of two or more. A structural unit derived from an unsaturated imide, specifically N-substituted maleimide, among the above is more preferable in terms of improvement in the copolymerizability, control of the flowability of a pattern, and complement for insufficient development.

The amount of the structural unit (a-4) may be 0 to 80% by mole, preferably 10 to 75% by mole, based on the total moles of the structural units constituting the copolymer. Within the above amount range, the storage stability of a colored photosensitive resin composition may be maintained, and the film retention rate may be more advantageously improved.

Examples of the copolymer having the structural units (a-1) to (a-4) may include a copolymer of (meth)acrylic acid/styrene/methyl (meth)acrylate/glycidyl (meth)acrylate, a copolymer of (meth)acrylic acid/styrene/methyl (meth)acrylate/glycidyl (meth)acrylate/N-phenylmaleimide, a copolymer of (meth)acrylic acid/styrene/methyl (meth)acrylate/glycidyl (meth)acrylate/N-cyclohexylmaleimide, a copolymer of (meth)acrylic acid/styrene/n-butyl (meth)acrylate/glycidyl (meth)acrylate/N-phenylmaleimide, a copolymer of (meth)acrylic acid/styrene/glycidyl (meth)acrylate/N-phenylmaleimide, a copolymer of (meth)acrylic acid/styrene/4-hydroxybutyl (meth)acrylate glycidyl ether/N-phenylmaleimide, and the like.

One, two, or more of the copolymers may be comprised in the colored photosensitive resin composition.

The weight average molecular weight (Mw) of the copolymer may be in the range of 5,000 to 30,000, preferably 10,000 to 20,000, when determined by gel permeation chromatography (eluent: tetrahydrofuran) referenced to polystyrene. Within the above range, the step difference by a lower pattern may be advantageously improved, and a pattern profile upon development may be favorable, as well as it may be more favorable in terms of adhesiveness to a substrate, physical and chemical properties, and viscosity.

The amount of the copolymer in the colored photosensitive resin composition may be 5 to 60% by weight, preferably 8 to 45% by weight, based on the total weight of the solid content (i.e., the weight excluding solvents) of the colored photosensitive resin composition. Within the above range, a pattern profile upon development may be favorable, and such properties as film retention rate and chemical resistance may be improved.

The copolymer may be prepared by charging to a reactor a radical polymerization initiator, a solvent, and the structural units (a-1) to (a-4), followed by charging nitrogen thereto and slowly stirring the mixture for polymerization.

The radical polymerization initiator may be an azo compound such as 2,2′-azobisisobutyronitrile, 2,2′-azobis(2,4-dimethylvaleronitrile), and 2,2′-azobis(4-methoxy-2,4-dimethylvaleronitrile); or benzoyl peroxide, lauryl peroxide, t-butyl peroxypivalate, 1,1-bis(t-butylperoxy)cyclohexane, or the like, but is not limited thereto.

The radical polymerization initiator may be used alone or in combination of two or more.

The solvent may be any conventional solvent commonly used in the preparation of a copolymer and may include, for example, propylene glycol monomethyl ether acetate (PGMEA).

(B) Photopolymerizable Compound Comprising a Double Bond

The photopolymerizable compound employed in the present invention is a compound that has a double bond and is polymerizable by the action of a polymerization initiator. Specifically, the photopolymerizable compound may comprise a monofunctional or polyfunctional ester compound having at least one ethylenically unsaturated double bond and may preferably comprise a polyfunctional compound having at least two functional groups from the view point of chemical resistance.

The photopolymerizable compound may be selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid, pentaerythritol tetra(meth)acrylate, dipentaerythritol penta(meth)acrylate, dipentaerythritol hexa(meth)acrylate, a monoester of dipentaerythritol penta(meth)acrylate and succinic acid, pentaerythritol triacrylate-hexamethylene diisocyanate (a reaction product of pentaerythritol triacrylate and hexamethylene diisocyanate), tripentaerythritol hepta(meth)acrylate, tripentaerythritol octa(meth)acrylate, bisphenol A epoxyacrylate, and ethylene glycol monomethyl ether acrylate, and a mixture thereof, but is not limited thereto.

Examples of the photopolymerizable compound commercially available may include (i) monofunctional (meth)acrylate such as Aronix M-101, M-111, and M-114 manufactured by Toagosei Co., Ltd., KAYARAD T4-110S and T4-120S manufactured by Nippon Kayaku Co., Ltd., and V-158 and V-2311 manufactured by Osaka Yuki Kayaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kayaku Kogyo Co., Ltd.; and (iii) tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, and DPHA-40H manufactured by Nippon Kayaku Co., Ltd., and V-295, V-300, V-360, V-GPT, V-3PA, V-400, and V-802 manufactured by Osaka Yuki Kayaku Kogyo Co., Ltd.

The amount of the photopolymerizable compound may be 10 to 400 parts by weight, preferably 50 to 300 parts by weight, based on 100 parts by weight of the copolymer (A). Within the above amount range, a pattern may be readily developed, and such properties as chemical resistance and elastic restoring force may be improved. If the amount is less than 10 parts by weight, the development time may be prolonged, which may affect the process and residues. If the amount exceeds 400 parts by weight, it may cause a poor pattern resolution and the generation of wrinkles.

The molar ratio of the double bonds in the photopolymerizable compound (B) to the epoxy groups in the copolymer (A) may satisfy the following relationships:

4≤number of moles of double bonds/number of moles of epoxy groups≤35

or

11≤number of moles of double bonds/number of moles of epoxy groups≤35.

If uneven wrinkles are generated on the surface of a display bezel, it may cause a disadvantage that the amount of injected liquid crystals may not be uniform due to a defect in the gap between the upper and lower plates during their assembly or that spots may be generated on the display screen due to a poor transmission of electric signals. Within the above range, it is possible to minimize the generation of uneven wrinkles on the surface of a cured film when it is formed from the colored photosensitive resin composition and to form a step difference and a pattern in a high resolution.

If the molar ratio exceeds 35, the curing of the surface of a coated film during the exposure to light is strongly taken place, while materials having unreacted double bonds remain in its interior, which raises the flowability (i.e., mobility) of such unreacted materials in the subsequent thermal curing process. As a result, the polymer near the surface and the polymer deep inside the pattern would have different mobilities during the thermal curing, resulting in uneven wrinkles on the surface of the cured film. In addition, if the molar ratio is less than 4, it is difficult to control the degree of crosslinking in accordance with changes in the temperature since the number of moles of epoxy groups is relatively larger than the number of moles of double bonds, which makes poor the development margins in accordance with temperature changes during the process and, thus, lowers the resolution.

(C) Photopolymerization Initiator

The colored photosensitive resin composition of the present invention comprises an oxime ester fluorene-based initiator represented by the following Formula 1 as a photopolymerization initiator:

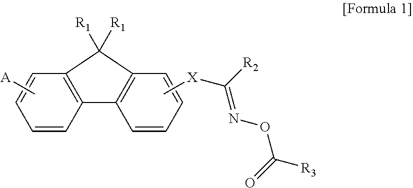

In Formula 1 above, R₁ is each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, or C₁₋₂₀ hydroxyalkoxyalkyl,

R₂ and R₃ are each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, C₁₋₂₀ hydroxyalkoxyalkyl, or C₄₋₂₀ heterocycle,

X is a single bond or carbonyl,

A is hydrogen, C₁₋₂₀ alkyl, C₆₋₃₀ aryl, C₁₋₂₀ alkoxy, C₇₋₃₀ arylalkyl, C₁₋₂₀ hydroxyalkyl, C₁₋₂₀ hydroxyalkoxyalkyl, C₃₋₂₀ cycloalkyl, amino, hydroxy, nitro, cyano, or

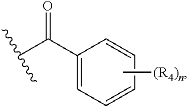

R₄ is R₅, OR₅, SR₅, COR₅, CONR₅R₅, NR₅COR₅, OCOR₅, COOR₅, SCOR₅, OCSR₅, COSR₅, CSOR₅, CN, halogen, or hydroxy,

R₅ is each independently C₁₋₂₀ alkyl, C₆₋₃₀ aryl, C₇-30 arylalkyl, or C₄₋₂₀ heterocycle,

n is an integer of 0 to 4.

The heterocycle may be a 5- or 6-membered monocyclic ring containing 1 to 3 heteroatoms selected from O, N, and S.

Preferably, R₁ may be each independently hydrogen, bromo, chloro, iodo, phenyl, naphthyl, biphenyl, terphenyl, anthryl, indenyl, phenanthryl, methoxy, ethoxy, n-propyloxy, i-propyloxy, n-butoxy, i-butoxy, t-butoxy, hydroxymethyl, hydroxyethyl, hydroxy n-propyl, hydroxy n-butyl, hydroxy i-butyl, hydroxy n-pentyl, hydroxy i-pentyl, hydroxy n-hexyl, hydroxy i-hexyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, hydroxyethoxypentyl, hydroxyethoxyhexyl, methyl, ethyl, n-propyl, i-propyl, n-butyl, i-butyl, t-butyl, n-pentyl, i-pentyl, n-hexyl, or i-hexyl; and

R₂ and R₃ may be each independently hydrogen, bromo, chloro, iodo, methoxy, ethoxy, n-propyloxy, i-propyloxy, n-butoxy, i-butoxy, t-butoxy, hydroxymethyl, hydroxyethyl, hydroxy n-propyl, hydroxy n-butyl, hydroxy i-butyl, hydroxy n-pentyl, hydroxy i-pentyl, hydroxy n-hexyl, hydroxy i-hexyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, hydroxyethoxypentyl, hydroxyethoxyhexyl, methyl, ethyl, n-propyl, i-propyl, n-butyl, i-butyl, t-butyl, n-pentyl, i-pentyl, n-hexyl, i-hexyl, phenyl, naphthyl, biphenyl, terphenyl, anthryl, indenyl, or phenanthryl.

A may be hydrogen, methyl, ethyl, n-propyl, i-propyl, n-butyl, i-butyl, t-butyl, phenyl, naphthyl, biphenyl, terphenyl, anthryl, indenyl, phenanthryl, methoxy, ethoxy, propyloxy, butoxy, hydroxymethyl, hydroxyethyl, hydroxypropyl, hydroxybutyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, amino, nitro, cyano, or hydroxy.

More preferably, R₁ may be each independently methyl, ethyl, n-propyl, i-propyl, n-butyl, i-butyl, t-butyl, n-pentyl, i-pentyl, n-hexyl, or i-hexyl; and

R₂ and R₃ may be each independently methyl, ethyl, n-propyl, i-propyl, n-butyl, i-butyl, t-butyl, n-pentyl, i-pentyl, n-hexyl, i-hexyl, phenyl, naphthyl, biphenyl, terphenyl, anthryl, indenyl, or phenanthryl.

A may be nitro, cyano, or hydroxy.

The oxime ester fluorene-based photopolymerization initiator may be synthesized according to a conventional method or may be purchased commercially.

The oxime ester fluorene-based photopolymerization initiator of Formula 1 above serves as a crosslinking agent as well as a high-sensitivity initiator for a colored to photosensitive resin composition. The oxime ester fluorene-based photopolymerization initiator in the colored photosensitive resin composition enhances the efficiency to light (or enhancement in the photosensitivity), so that it is capable of suppressing the generation of outgassing, which is a contamination source, during the process. In addition, the oxime ester fluorene-based photopolymerization initiator of Formula 1 above can provide sufficient high-sensitivity characteristics such as elastic recovery rate, resolution, formation of a step difference, and the like, even when only a small amount thereof is used, thereby complementing the disadvantage of a colored resin composition that has insufficient optical efficiency.

The photopolymerization initiator of Formula 1 above may be employed in an amount of 0.01 to 15 parts by weight, preferably of 0.01 to 10 parts by weight, more preferably 0.1 to 10 parts by weight, based on 100 parts by weight of the copolymer (A). Within the above amount range, a coated film having an excellent degree of curing in the entire pattern may be obtained since the sensitivity can be complemented.

The photopolymerization initiator (C) may further comprise a triazine-based initiator represented by the following Formula 2:

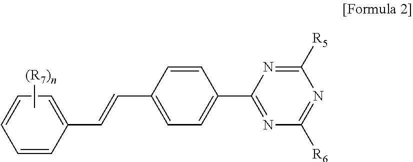

In Formula 2 above, R₅ and R₆ are each independently a halomethyl group, R₇ is each independently hydrogen, C₁₋₄ alkyl, or C₁₋₄ alkoxy, and n is an integer of 0 to 3.

Specifically, the triazine-based compound of Formula 2 above may be a compound represented by the following Formula 2a:

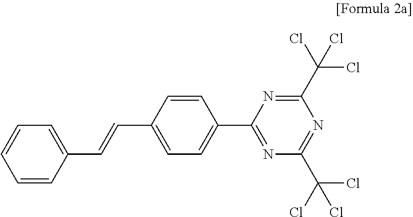 [SMILES: ClC(Cl)(Cl)c1nc(-c2ccc(/C=C/c3ccccc3)cc2)nc(C(Cl)(Cl)Cl)n1]

The oxime ester fluorene-based photopolymerization initiator of Formula 1 above is a high-sensitive, short-wavelength initiator, while the triazine-based photoinitiator of Formula 2 above is a long-wavelength initiator. Thus, in the case where the oxime ester fluorene-based photoinitiator and the triazine-based photoinitiator are used together, it is easier to form a step difference in a black column spacer, and it is possible to improve the light exposure margins and the sensitivity at the same time. In such event, the compound of Formula 1 above and the compound of Formula 2 above may be used in a weight ratio of 2:8 to 8:2, preferably 2.5:7.5 to 7.5:2.5, more preferably 3:7 to 7:3. Within the above range, the curing can be sufficiently performed by exposure to light, which can be more advantageous for achieving excellent sensitivity and light exposure margins.

The colored photosensitive resin composition of the present invention may further comprise other photopolymerization initiators than those described above. Here, the additional photopolymerization initiators may be any known photopolymerization initiators.

The additional photopolymerization initiators may be selected from the group consisting of an acetophenone-based compound, a non-imidazole-based compound, an onium salt-based compound, a benzoin-based compound, a benzophenone-based compound, a diketone-based compounds, an α-diketone-based compound, a polynuclear quinone-based compound, a thioxanthone-based compound, a diazo-based compound, an imidesulfonate-based compound, a carbazole-based compound, a sulfonium borate-based compound, and a mixture thereof.

(D) Colorant

The colored photosensitive resin composition of the present invention comprises a colorant to impart the light shielding property thereto. The colorant employed in the present invention may be a mixture of two or more inorganic or organic colorants. It preferably has high chromogenicity and high heat resistance.

Specifically, the colorant may be at least one selected from the group consisting of a black colorant and a colorant other than black. The black colorant may be at least one selected from the group consisting of a black inorganic colorant and a black organic colorant. The colorant other than black may be at least one selected from the group consisting of a blue colorant and a violet colorant.

Any black inorganic colorant, any black organic colorant, and any colorant other than black known in the art may be used. For example, any compounds classified as a pigment in the Color Index (published by The Society of Dyers and Colourists) and any dyes known in the art may be used.

Particular examples of the black inorganic colorant may include carbon black, titanium black, a metal oxide such as Cu—Fe—Mn-based oxide and synthetic iron black, and the like. Preferred among them is carbon black in view of pattern characteristics and chemical resistance.

Particular examples of the black organic colorant may include aniline black, lactam black, perylene black, and the like. Preferred among them is lactam black (e.g., Black 582 from BASF) in view of optical density, dielectricity, and the like.

Particular examples of the colorant other than black may include C.I. Pigment Yellow 20, 24, 31, 53, 83, 86, 93, 94, 109, 110, 117, 125, 137, 138, 139, 147, 148, 150, 153, 154, 166, 173, 180, and 185; C.I. Pigment Orange 13, 31, 36, 38, 40, 42, 43, 51, 55, 59, 61, 64, 65, and 71; C.I. Pigment Red 9, 97, 105, 122, 123, 144, 149, 166, 168, 176, 177, 179, 180, 192, 215, 216, 224, 242, 254, 255, and 264; C.I. Pigment Violet 13, 14, 19, 23, 25, 27, 29, 32, 33, 36, 37, and 38; C.I. Pigment Blue 15 (15:3, 15:4, 15:6, and so on), 16, 21, 28, 60, 64, and 76; C.I. Pigment Green 7, 10, 15, 25, 36, 47, and 58; C.I. Pigment Brown 28, and the like.

Preferred among them are C.I. Pigment Blue 15:6 and 60, and C.I. Pigment Violet 23, for the purpose of preventing light leakage and light blurring phenomena and in terms of the dispersibility and the chemical resistance of a colored photosensitive resin composition.

The amount of the colorant may be 5 to 70% by weight, or 8 to 50% by weight, based on the total weight of the solid content (i.e., the weight excluding solvents) of the colored photosensitive resin composition. Specifically, the colorant may comprise 0 to 15% by weight of a black inorganic colorant, 0 to 40% by weight of a black organic colorant, and 0 to 20% by weight of a colorant other than black based on the total weight of the solid content (i.e., the weight excluding solvents) of the colored photosensitive resin composition. If the amount of the colorant is within the above range, a pattern profile upon development may be favorable, such properties as chemical resistance and elastic restoring force may be improved, and it is possible to achieve an optical density and a light transmittance as desired.

Meanwhile, the colorant used in the present invention may be added to the colored photosensitive resin composition in the form of a mill base as mixed with a dispersion resin, a solvent, or the like.

The dispersion resin serves to uniformly disperse a pigment in a solvent and may be specifically at least one selected from the group consisting of a dispersant and a dispersion binder.

Examples of the dispersant may include any known dispersant for a colorant. As particular examples thereof, the dispersant may be selected from the group consisting of a cationic surfactant, an anionic surfactant, a non-ionic surfactant, a zwitterionic surfactant, a silicon-based surfactant, a fluorine-based surfactant, a polyester-based compound, a polycarboxylic acid ester-based compound, an unsaturated polyamide-based compound, a polycarboxylic acid-based compound, a polycarboxylic acid alkyl salt compound, a polyacrylic compound, a polyethyleneimine-based compound, a polyurethane-based compound, polyurethane, a polycarboxylic acid ester represented by polyacrylate, unsaturated polyamide, polycarboxylic acid, an amine salt of polycarboxylic acid, an ammonium salt of polycarboxylic acid, an alkylamine salt of polycarboxylic acid, polysiloxane, a long chain polyaminoamide phosphate salt, an ester of polycarboxylic acid whose hydroxyl group is substituted and its modified product, an amide formed by reaction of polyester having a free carboxyl group with a poly(lower alkyleneimine) or a salt thereof, a (meth)acrylic acid-styrene copolymer, a (meth)acrylic acid-(meth)acrylate ester copolymer, a styrene-maleic acid copolymer, polyvinyl alcohol, a water-soluble resin or a water-soluble polymer compound such as polyvinylpyrrolidone; polyester; modified polyacrylate; an adduct of ethylene oxide/propylene oxide; a phosphate ester, and a combination thereof. Commercially available dispersants may include Disperbyk-182, -183, -184, -185, -2000, -2150, -2155, -2163, and -2164 from BYK Co. These compounds may be used alone or in combination of two or more. The dispersant may have an amine group and/or an acid group as a pigment-affinity group and may optionally be of an ammonium salt type.

The dispersant may be added in advance to a colorant through surface treatment of the colorant therewith or added together with a colorant at the time of preparing a colored photosensitive resin composition.

The amine value of the dispersant may be 10 to 200 mg KOH/g, 40 to 200 mg KOH/g, or 50 to 150 mg KOH/g. If the amine value of the dispersant is within the above range, the dispersibility and storage stability of the colorant are excellent, and the roughness of the surface of a cured film formed from the resin composition is improved.

The dispersant may be employed in an amount of 1 to 20% by weight, or 2 to 15% by weight, based on the total weight of the colored dispersion. If the amount of the dispersant is within the above range, the colorant is effectively dispersed to improve the dispersion stability, and the optical, physical, and chemical properties are improved by virtue of maintaining an appropriate viscosity when it is applied. Thus, it is desirable in terms of an excellent balance between dispersion stability and viscosity.

Further, the colorant comprises a dispersion resin, and the dispersion resin has an amine value of 3 mg KOH/g or less and may comprise 30% by mole or less of a maleimide monomer based on the total number of moles of the constituent units. In such event, the dispersion resin may be a dispersion binder.

If the amine value of the dispersion binder exceeds 3 mg KOH/g, the stability of the dispersant encircling the pigment may be adversely affected, which may in turn adversely affect the storage stability of the entire resin composition. Thus, the amine value of the dispersion binder is preferably 3 mg KOH/g or less. If the amine value of the dispersion binder is within the above range, the unexposed portion can be readily developed in the development process, and such problems as residues generation can be improved.

If the dispersion binder has an acid value, it may comprise a monomer having a carboxyl group and an unsaturated bond. Particular examples of the monomer having a carboxyl group and an unsaturated bond include a monocarboxylic acid such as acrylic acid, methacrylic acid, and crotonic acid; a dicarboxylic acid such as fumaric acid, mesaconic acid, and itaconic acid, and an anhydride of the dicarboxylic acid; a mono(meth)acrylate of a polymer having a carboxyl group and a hydroxyl group at both terminals such as ω-carboxypolycaprolactonemono(meth)acrylates, and the like. Preferred are acrylic acid and methacrylic acid.

In addition, the dispersion binder may comprise a monomer having a carboxyl group and an unsaturated bond and a monomer having a copolymerizable unsaturated bond.

Examples of the monomer having a copolymerizable unsaturated bond may, for example, include an aromatic vinyl compound such as styrene, vinyltoluene, α-methylstyrene, p-chlorostyrene, o-methoxystyrene, m-methoxystyrene, p-methoxystyrene, o-vinylbenzyl methyl ether, m-vinylbenzyl methyl ether, p-vinylbenzyl methyl ether, o-vinyl benzyl glycidyl ether, m-vinyl benzyl glycidyl ether, and p-vinylbenzyl glycidyl ether; an alkyl (meth)acrylate such as methyl (meth)acrylate, ethyl (meth)acrylate, n-propyl (meth)acrylate, i-propyl (meth)acrylate, n-butyl (meth)acrylate, i-butyl (meth)acrylate, sec-butyl (meth)acrylate, and t-butyl (meth)acrylate; an alicyclic (meth)acrylates such as cyclopentyl (meth)acrylate, cyclohexyl (meth)acrylate, 2-methylcyclohexyl (meth)acrylate, tricyclo[5.2.1.0.2.6]decan-8-yl (meth)acrylate, 2-dicyclopentanyloxyethyl (meth)acrylate, and isobornyl (meth)acrylate; an aryl (meth)acrylate such as phenyl (meth)acrylate and benzyl (meth)acrylate; a hydroxyalkyl (meth)acrylate such as 2-hydroxyethyl (meth)acrylate and 2-hydroxypropyl (meth)acrylate; an N-substituted maleimide compound such as N-cyclohexylmaleimide, N-benzylmaleimide, N-phenylmaleimide, N-o-hydroxyphenylmaleimide, N-m-hydroxyphenylmaleimide, N-p-hydroxyphenylmaleimide, N-o-methylphenylmaleimide, N-m-methylphenylmaleimide, N-p-methylphenylmaleimide, N-o-methoxyphenylmaleimide, N-m-methoxyphenylmaleimide, and N-p-methoxyphenylmaleimide; an unsaturated amide compound such as (meth)acrylamide and N,N-dimethyl (meth)acrylamide; and an unsaturated oxetane compound such as 3-(methacryloyloxymethyl)oxetane, 3-(methacryloyloxymethyl)-3-ethyloxetane, 3-(methacryloyloxymethyl)-2-trifluoromethyloxetane, 3-(methacryloyloxymethyl)-2-phenyloxetane, 2-(methacryloyloxymethyl)oxetane, and 2-(methacryloyloxymethyl)-4-trifluoromethyloxetane, which may be used alone or in combination of two or more.

The dispersion binder may have an acid value of 30 to 200 mg KOH/g. Specifically, the dispersion binder may have an acid value of 50 to 150 mg KOH/g. If the acid value of the dispersion binder is within the above range, the impact of the dispersant encircling the pigment on the amine value is reduced, thereby producing the effects of excellent stability of the colored dispersion and uniform particle size.

The dispersion binder may be employed in an amount of 1 to 20% by weight, or 2 to 15% by weight, based on the total weight of the colored dispersion. If the dispersion binder is employed in the above amount range, the resin composition can maintain an appropriate viscosity level, and it is preferable in terms of dispersion stability and developability.

The total amount of the colorants may be 50 to 500 parts by weight, preferably 100 to 400 parts by weight, based on 100 parts by weight of the copolymer (A). Within the above amount range, a pattern profile upon development may be favorable. If the amount is less than 50 parts by weight or exceeds 500 parts by weight, an optical density and a transmittance as desired cannot be obtained.

(E) Compound Derived from an Epoxy Resin and Having a Double Bond

The colored photosensitive resin composition of the present invention may further comprise a compound derived from an epoxy resin and having a double bond. The compound derived from an epoxy resin has at least one double bond and may have a cardo backbone structure. Further, it may be a resin containing a double bond in its side chain derived from a functional group contained in a novolak-based resin or an acrylic-based resin.

The weight average molecular weight (Mw) of the compound derived from an epoxy resin may be in the range of 3,000 to 18,000, preferably 5,000 to 10,000, when determined by gel permeation chromatography referenced to polystyrene. Within the above range, the step difference by a lower pattern may be advantageously improved, and a pattern profile upon development may be favorable.

Specifically, the epoxy resin may be a compound having a cardo backbone structure as represented by the following Formula 3.

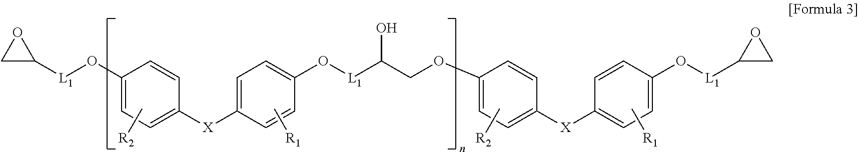

In Formula 3 above, X is each independently

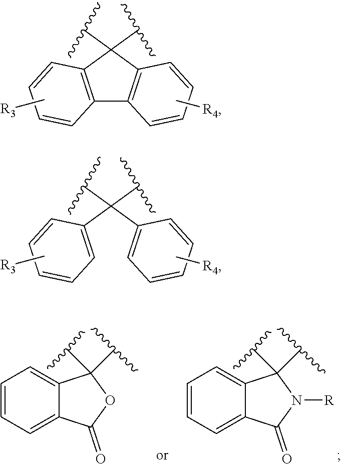

L¹ is each independently a C₁₋₁₀ alkylene group, a C₃₋₂₀ cycloalkylene group, or a C₁₋₁₀ alkyleneoxy group; R₁ to R₇ are each independently H, a C₁₋₁₀ alkyl group, a C₁₋₁₀ alkoxy group, a C₂₋₁₀ alkenyl group, or a C₆₋₁₄ aryl group; R₅ is H, methyl, ethyl, CH₃CHCl—, CH₃CHOH—, CH₂═CHCH₂—, or phenyl; and n is an integer from 0 to 10.

Particular examples of the C₁₋₁₀ alkylene group may include methylene, ethylene, propylene, isopropylene, butylene, isobutylene, sec-butylene, t-butylene, pentylene, isopentylene, t-pentylene, hexylene, heptylene, octylene, isooctylene, t-octylene, 2-ethylhexylene, nonylene, isononylene, decylene, isodecylene, and the like.

Particular examples of the C₃₋₂₀ cycloalkylene group may include cyclopropylene, cyclobutylene, cyclopentylene, cyclohexylene, cycloheptylene, decalinylene, adamantylene, and the like.

Particular examples of the C₁₋₁₀ alkyleneoxy group may include methyleneoxy, ethyleneoxy, propyleneoxy, butyleneoxy, sec-butyleneoxy, t-butyleneoxy, pentyleneoxy, hexyleneoxy, heptyleneoxy, octyleneoxy, 2-ethyl-hexyleneoxy, and the like.

Particular examples of the C₁₋₁₀ alkyl group may include methyl, ethyl, propyl, isopropyl, butyl, isobutyl, sec-butyl, t-butyl, pentyl, isopentyl, t-pentyl, hexyl, heptyl, octyl, isooctyl, t-octyl, 2-ethylhexyl, nonyl, isononyl, decyl, isodecyl, and the like.

Particular examples of the C₁₋₁₀ alkoxy group may include methoxy, ethoxy, propoxy, butyloxy, sec-butoxy, t-butoxy, pentoxy, hexyloxy, heptoxy, octyloxy, 2-ethyl-hexyloxy, and the like.

Particular examples of the C₂₋₁₀ alkenyl group may include vinyl, allyl, butenyl, propenyl, and the like.

Particular examples of the C₆₋₁₄ aryl group may include phenyl, tolyl, xylyl, naphthyl, and the like.

As an example, the epoxy resin having a cardo backbone structure may be prepared through the following synthesis route:

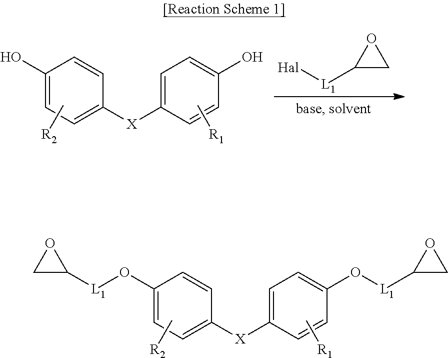

In Reaction Scheme 1 above, Hal is a halogen; and X, R₁, R₂, and L₁ are the same as defined in Formula 2.

The compound derived from the epoxy resin having a cardo backbone structure may be obtained by reacting the epoxy resin having a cardo backbone structure with an unsaturated basic acid to produce an epoxy adduct and then reacting the epoxy adduct thus obtained with a polybasic acid anhydride, or by further reacting the product thus obtained with a monofunctional or polyfunctional epoxy compound. Any unsaturated basic acid known in the art, e.g., acrylic acid, methacrylic acid, crotonic acid, cinnamic acid, sorbic acid, and the like, may be used. Any polybasic acid anhydride known in the art, e.g., succinic anhydride, maleic anhydride, trimellitic anhydride, pyromellitic anhydride, 1,2,4,5-cyclohexane tetracarboxylic dianhydride, hexahydrophthalic anhydride, and the like, may be used. Any monofunctional or polyfunctional epoxy compound known in the art, e.g., glycidyl methacrylate, methyl glycidyl ether, ethyl glycidyl ether, propyl glycidyl ether, isopropyl glycidyl ether, butyl glycidyl ether, isobutyl glycidyl ether, bisphenol Z glycidyl ether, and the like, may be used.

As an example, the compound derived from the epoxy resin having a cardo backbone structure may be prepared through the following synthesis route:

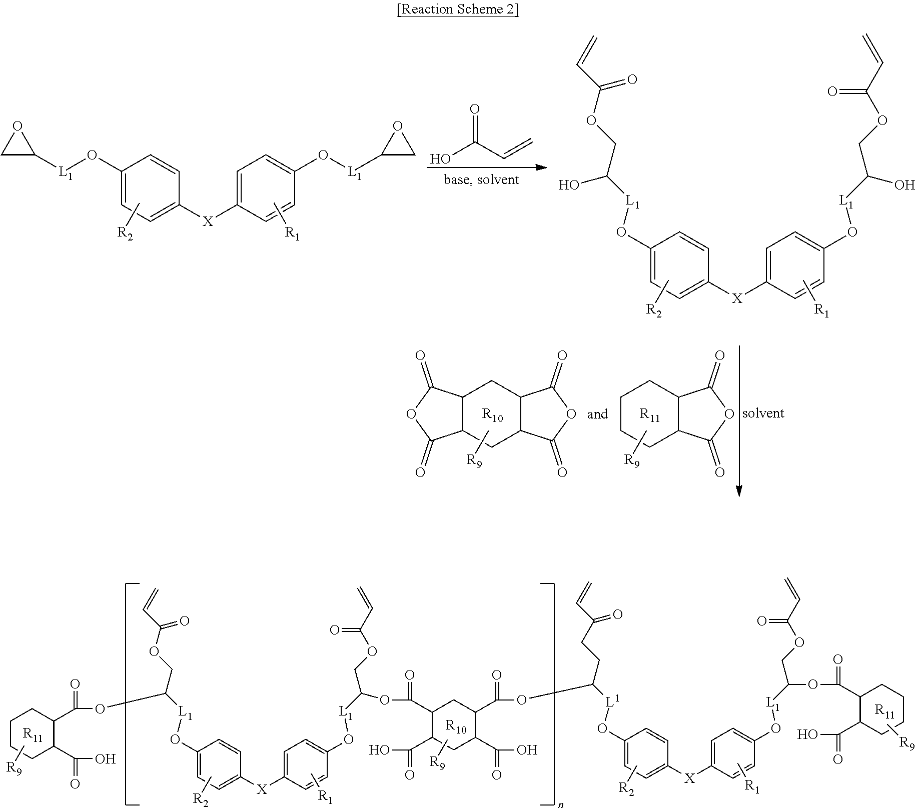

In Reaction Scheme 2 above, R₉ is each independently H, a C₁₋₁₀ alkyl group, a C₁₋₁₀ alkoxy group, a C₂₋₁₀ alkenyl group, or a C₆₋₁₄ aryl group; R₁₀ and R₁₁ are each independently a saturated or unsaturated C₆ aliphatic ring or a benzene ring; n is an integer from 1 to 10; and X, R₁, R₂, and L₁ are the same as defined in Formula 2.

In the case where the compound derived from the epoxy resin having a cardo backbone structure is used, the cardo backbone structure may improve the adhesiveness of a cured material to a substrate, alkaline resistance, processability, strength, and the like. Further, an image in a fine resolution may be formed in a pattern once an uncured part is removed upon development.

Examples of the novolak-based resin may include, for example, a phenol novolak-based epoxy compound, a biphenyl novolak-based epoxy compound, a cresol novolak-based epoxy compound, a bisphenol A novolak-based epoxy compound, a dicyclopentadiene novolak-based epoxy compound, and the like.

The amount of the compound derived from an epoxy resin may be 10 to 300 parts by weight, preferably 50 to 250 parts by weight, based on 100 parts by weight of the copolymer (A). Within the above amount range, a pattern profile upon development may be favorable, the sensitivity and the elastic recovery rate are improved, and it is possible to control the development characteristics.

In the colored photosensitive resin composition of the present invention, the molar ratio of the double bonds in the photopolymerizable compound (B) and in the compound derived from an epoxy resin (E) to the epoxy groups in the copolymer (A) satisfies the following relationships:

4≤number of moles of double bonds/number of moles of epoxy groups≤35

or

11≤number of moles of double bonds/number of moles of epoxy groups≤35.

(F) Epoxy Compound

The colored photosensitive resin composition of the present invention may further comprise an epoxy compound so as to increase the internal density of the resin, to thereby improve the chemical resistance of a cured film prepared therefrom.

The epoxy compound may be an unsaturated monomer containing at least one epoxy group, or a homo-oligomer or a hetero-oligomer thereof. Examples of the unsaturated monomer containing at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, glycidyl (meth)acrylate may be used.

Examples of the commercially available homo-oligomer of an unsaturated monomer containing at least one epoxy group may include GHP03 (glycidyl methacrylate, Miwon Commercial Co., Ltd.).

The epoxy compound may be synthesized according to a known method.

The epoxy compound (F) may further comprise the following structural unit.

Particular examples may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxystyrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether, and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the above exemplary compounds may be contained in the epoxy compound (F) alone or in combination of two or more thereof.

The epoxy compound (F) preferably has a weight average molecular weight of 100 to 30,000, more preferably may have a weight average molecular weight of 1,000 to 15,000. If the weight average molecular weight of the epoxy compound is 100 or more, the hardness of a thin film can be more excellent. If the weight average molecular weight of the epoxy compound is 30,000 or less, the thickness of a thin film becomes uniform with a smaller step difference, which is more suitable for planarization. The weight average molecular weight is determined by gel permeation chromatography (eluent: tetrahydrofuran) referenced to polystyrene.

The amount of the epoxy compound may be 0 to 30 parts by weight, or 0 to 20 parts by weight, based on 100 parts by weight of the copolymer (A). Within the above amount range, a pattern profile upon development may be favorable, and such properties as chemical resistance and elastic restoring force may be improved.

In the colored photosensitive resin composition of the present invention, the molar ratio of the double bonds in the photopolymerizable compound (B) to the epoxy groups in the copolymer (A) and in the epoxy compound (F) may satisfy the following relationships:

4≤number of moles of double bonds/number of moles of epoxy groups≤35

or

11≤number of moles of double bonds/number of moles of epoxy groups≤35.

In the colored photosensitive resin composition of the present invention, the molar ratio of the double bonds in the photopolymerizable compound (B) and in the compound derived from an epoxy resin (E) to the epoxy groups in the copolymer (A) and in the epoxy compound (F) may satisfy the above relationships.

(G) Surfactant

The colored photosensitive resin composition of the present invention may further comprise a surfactant so as to improve the coatability and to prevent generation of defects.

Although the kind of the surfactant is not particularly limited, for example, a fluorine-based surfactant or silicon-based surfactant may be used.

The commercially available silicon-based surfactant may include DC3PA, DC7PA, SH11PA, SH21PA, and SH8400 from Dow Corning Toray Silicon, TSF-4440, TSF-4300, TSF-4445, TSF-4446, TSF-4460, and TSF-4452 from GE Toshiba Silicone, BYK-333, BYK-307, BYK-3560, BYK UV-3535, BYK-361N, BYK-354, and BYK-399 from BYK, and the like. This surfactant may be used alone or in combination of two or more.

The commercially available fluorine-based surfactant may include Megaface F-470, F-471, F-475, F-482, F-489, and F-563 from Dainippon Ink Kagaku Kogyo Co. (DIC). Preferred among these surfactants may be BYK-333 and BYK-307 from BYK and F-563 from DIC in view of the coatability of the composition.

The surfactant may be employed in an amount of 0.01 to 10 parts by weight, preferably 0.1 to 1 part by weight, based on 100 parts by weight of the copolymer (A).

Within the above amount range, the colored photosensitive resin composition may be smoothly coated.

(H) Solvent

The colored photosensitive resin composition of the present invention may preferably be prepared as a liquid composition in which the above components are mixed with a solvent. Any solvent known in the art and used in the preparation of colored photosensitive resin compositions, which is compatible but not reactive with the components of the colored photosensitive resin composition, may be employed.

Examples of the solvent may include a glycol ether such as ethylene glycol monoethyl ether; an ethylene glycol alkyl ether acetate such as ethyl cellosolve acetate; an ester such as ethyl 2-hydroxypropionate; a diethylene glycol such as diethylene glycol monomethyl ether; a propylene glycol alkyl ether acetate such as propylene glycol monomethyl ether acetate and propylene glycol propyl ether acetate; and an alkoxyalkyl acetate such as 3-methoxybutyl acetate. The solvent may be used alone or in combination of two or more.

The amount of the solvent is not specifically limited, but may be 50 to 90% by weight, preferably 70 to 85% by weight, based on the total weight of the colored photosensitive resin composition in view of the coatability and the stability of the colored photosensitive resin composition finally obtained.

In addition, the colored photosensitive resin composition of the present invention may comprise other additives such as an antioxidant and a stabilizer as long as the physical properties of the colored photosensitive resin composition are not adversely affected.

Accordingly, the colored photosensitive resin composition of the present invention as described above comprises epoxy groups and double bonds in a specific molar ratio and an oxime ester fluorene-based photopolymerization initiator in a smaller amount than a conventional oxime ester-based photopolymerization initiator, so that it is possible to reduce the generation of outgassing, which is a contamination source that may be generated during the process. Since the colored photosensitive resin composition is excellent in such properties as surface smoothness, sensitivity, elastic recovery rate, resolution, chemical resistance, voltage retention rate, resistance to exudation, and the like; and is capable of forming a cured film that minimizes the generation of uneven wrinkles on its surface, it can be advantageously used as a material for forming a light shielding spacer such as a black column spacer to be employed in various electronic parts inclusive of an LCD panel and an OLED display panel.

The colored photosensitive resin composition of the present invention comprising the above-described components may be prepared by a common method, for example, by the following method.

First, a colorant is mixed with a solvent in advance and dispersed therein using a bead mill until the average particle diameter of the colorant reaches a desired level. In such event, a surfactant may be used, and a portion or the whole of a copolymer may be blended. Added to the dispersion thus obtained are the remainder of the copolymer and the surfactant, a compound derived from an epoxy resin, a photopolymerizable compound, and a photopolymerization initiator. An additive such as an epoxy compound or an additional solvent, if necessary, is further blended to a certain concentration, followed by sufficiently stirring them to obtain a desired colored photosensitive resin composition.

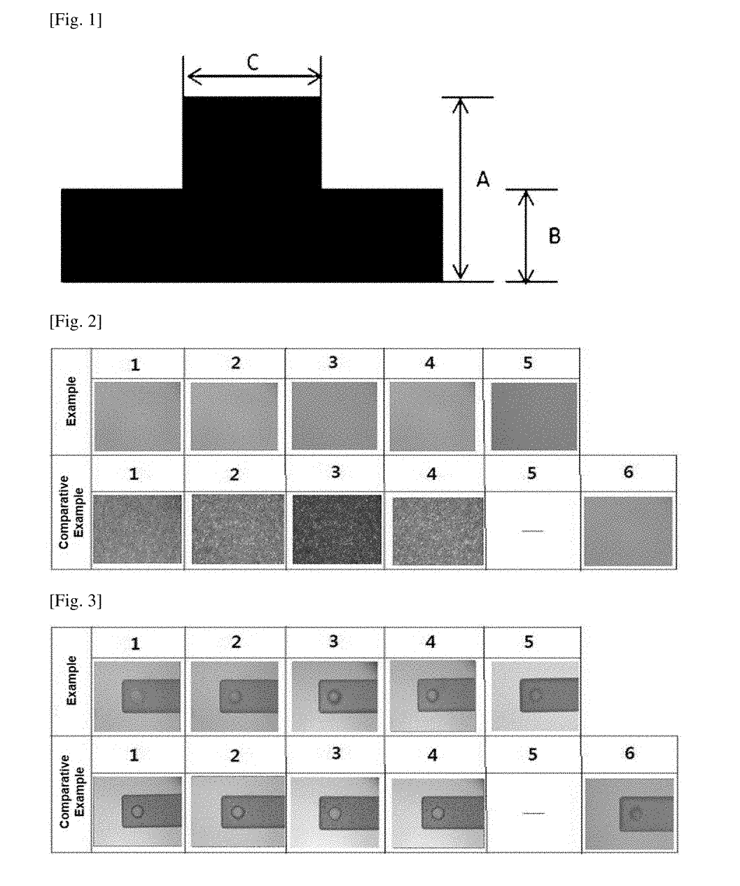

The present invention also provides a light shielding spacer produced from the colored photosensitive resin composition. Specifically, the present invention provides a black column spacer (BCS) produced from the colored photosensitive resin composition, in which a column spacer and a black matrix are integrated into a single module. An example of the pattern of the black column spacer is shown in FIG. 1.

The light shielding spacer may have an optical density of 0.5 to 2.0/m and an elastic recovery rate of 90% or more. Furthermore, the light shielding spacer must have a transmittance of 5% or less at the wavelength of about 700 nm when a cured film is formed in a thickness of 3 m so as to prevent a light blurring phenomenon of red or green color in the case where the light shielding spacer is employed in a display. In addition, the transmittance in the range of 900 nm to 950 nm must be 10% or more in order to facilitate recognition of the alignment key in the course of placing a mask for light exposure.

The column spacer, black matrix, or black column spacer may be prepared through a coating formation step, a light exposure step, a development step, and a thermal treatment step.

In the coating formation step, the colored photosensitive resin composition according to the present invention is coated on a pre-treated substrate by a spin coating method, a slit coating method, a roll coating method, a screen printing method, an applicator method, or the like in a desired thickness, for example, 1 to 25 μm, which is then pre-cured at a temperature of 70 to 100° C. for 1 to 10 minutes to form a coating by removing the solvent therefrom.

In order to form a pattern on the coated film, a mask having a predetermined shape is placed thereon, which is then irradiated with activated rays having 200 to 500 nm. In such event, in order to produce an integrated-type black column spacer, a mask having patterns with different transmittances may be used to prepare a column spacer and a black matrix at the same time. As a light source used for the irradiation, a low-pressure mercury lamp, a high-pressure mercury lamp, an extra high-pressure mercury lamp, a metal halide lamp, an argon gas laser, or the like may be used; and X-rays, electronic rays, or the like may also be used, if desired. The rate of light exposure may vary depending on the kind and the compositional ratio of the components of the composition and the thickness of a dried coating. If a high-pressure mercury lamp is used, the rate of light exposure may be 500 mJ/cm² or less (at the wavelength of 365 nm).

Subsequent to the light exposure step, an aqueous alkaline solution such as sodium carbonate, sodium hydroxide, potassium hydroxide, tetramethylammonium hydroxide, or the like may be used as a developing solvent to dissolve and remove unnecessary portions, whereby only an exposed portion remains to form a pattern. An image pattern obtained by the development is cooled to room temperature and post-baked in a hot air circulation-type drying furnace at a temperature of 180 to 250° C. for 10 to 60 minutes, thereby obtaining a final pattern.

The light shielding spacer thus produced may be used in the manufacture of electronic parts of an LCD, an OLED display, and the like by virtue of its excellent physical properties. Thus, the present invention provides an electronic part comprising the light shielding spacer.

The LCD, OLED display, and the like may comprise other components known to those skilled in the art, except that they are provided with the light shielding spacer of the present invention. That is, an LCD, an OLED display, and the like, to which the light shielding spacer of the present invention can be applied, may fall within the scope of the present invention.

Hereinafter, the present invention will be described in more detail with reference to the following examples. However, these examples are set forth to illustrate the present invention, and the scope of the present invention is not limited thereto.

### Preparation Example 1: Preparation of a Copolymer (A)

A 500 ml, round-bottomed flask equipped with a refluxing condenser and a stirrer was charged with 100 g of a monomer mixture consisting of 51% by mole of N-phenylmaleimide (N-PMI), 4% by mole of styrene (Sty), 10% by mole of 4-hydroxybutyl acrylate glycidyl ether (4-HBAGE), and 35% by mole of methacrylic acid (MAA), along with 300 g of propylene glycol monomethyl ether acetate (PGMEA) as a solvent and 1.8 g of 2,2′-azobis(2,4-dimethylvaleronitrile) as a radical polymerization initiator. The mixture was then heated to 70° C. and stirred for 5 hours to obtain a copolymer (A) having a solid content of 31% by weight. The copolymer thus prepared had an acid value of 100 mg KOH/g and a weight average molecular weight (Mw) of 10,000 when measured by gel permeation chromatography and referenced to polystyrene.

### Preparation Example 2: Preparation of a Compound Derived from an Epoxy Resin and Having a Cardo Backbone Structure (E)

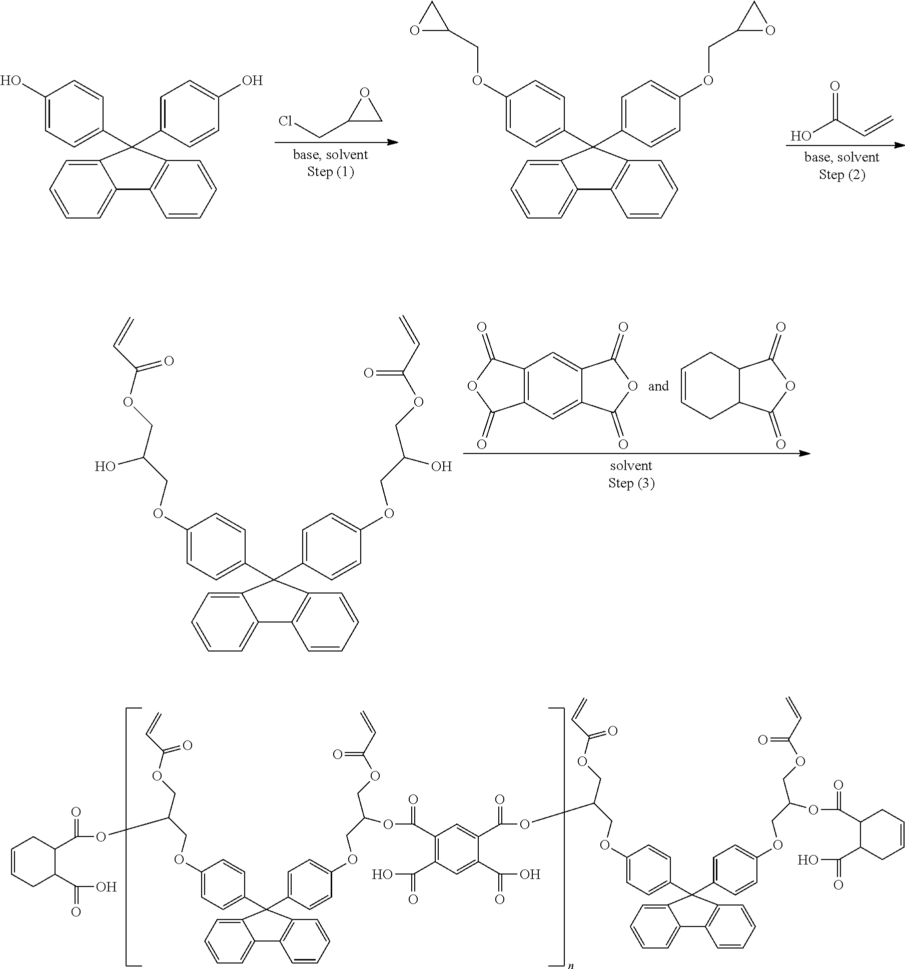

### Step (1): Preparation of 9,9-bis[4-(glycidyloxy)phenyl]fluorene

A 3,000 ml, three-neck round-bottomed flask was charged with 200 g of toluene, 125.4 g of 4,4′-(9-fluorenylidene)diphenol, and 78.6 g of epichlorohydrin, and the mixture was heated to 40° C. with stirring to be dissolved. 0.1386 g of t-butylammonium bromide and a 50% aqueous NaOH solution (3 eq.) were mixed in a vessel, and the mixture was slowly added to the solution being stirred in the flask.

The reaction mixture thus obtained was heated to 90° C. and reacted for 1 hour to completely consume 4,4′-(9-fluorenylidene)diphenol, which was confirmed by HPLC or TLC. The reaction mixture was cooled to 30° C., and 400 ml of dichloromethane and 300 ml of 1 N HCl were added thereto with stirring. Then, the organic layer was separated, washed with 300 ml of distilled water twice or three times, dried over magnesium sulfate, and distilled under a reduced pressure to remove dichloromethane. The resultant was recrystallized using a mixture of dichloromethane and methanol to thereby obtain the title compound, which is an epoxy resin compound.

### Step (2): Preparation of (((9H-fluorene-9,9-diyl)bis(4,1-phenylene))bis(oxy))bis(2-hydroxypropane-3,1-diyl) diacrylate (CAS No. 143182-97-2)

A 1,000 ml, three-necked flask was charged with 115 g of the compound obtained in step (1), 50 mg of tetramethylammonium chloride, 50 mg of 2,6-bis(1,1-dimethylethyl)-4-methylphenol, and 35 g of acrylic acid. The mixture was heated to 95° C. while air was blown at a flow rate of 25 ml/min, and it was further heated to 120° C. to be completely dissolved. The reaction mixture was stirred for about 12 hours until its acid value dropped to less than 1.0 mg KOH/g and then cooled to room temperature. Thereafter, 300 ml of dichloromethane and 300 ml of distilled water were added to the reaction mixture with stirring. The organic layer was separated, washed with 300 ml of distilled water twice or three times, dried over magnesium sulfate, and distilled under a reduced pressure to remove dichloromethane, thereby providing the title compound.

### Step (3): Preparation of a Compound Derived from an Epoxy Resin and Having a Cardo Backbone Structure

The compound obtained in step (2) in PGMEA was charged to a 1,000 ml, three-necked flask, and 1,2,4,5-benzenetetracarboxylic dianhydride (0.75 eq.), 1,2,3,6-tetrahydrophthalic anhydride (0.5 eq.), and triphenylphosphine (0.01 eq.) were further charged thereto. The reaction mixture was heated to 120-130° C. for 2 hours with stirring and then cooled to 85° C., which was stirred and heated for 6 hours. After the mixture was cooled to room temperature, a solution (solid content of 49% by weight) of a compound derived from an epoxy resin (E) having a weight average molecular weight (Mw) of 6,000 and an acid value of 107 mg KOH/g (based on the solid content) was obtained.

### Preparation Example 3: Preparation of a Colored Dispersion (D-1)

A colored dispersion was supplied from Tokushiki Co., Ltd., which dispersion had been prepared as follows.

8 g of an acrylic copolymer solution (a copolymer of benzyl methacrylate, styrene, and methacrylic acid) having a weight average molecular weight of 12,000 to 20,000 g/mole and an acid value of 80 to 150 mg KOH/g (Tokushiki Co., Ltd.), 8 g of an acrylic polymer dispersant having an amine value of 100 to 140 mg KOH/g (Tokushiki Co., Ltd.), 18 g of carbon black, 65 g of lactam black (Black 582, BASF) as an organic black, and 384 g of PGMEA as a solvent were dispersed using a paint shaker at 25° C. for 6 hours. This dispersion step was performed with 0.3 mm zirconia beads. Upon completion of the dispersion step, the beads were removed from the dispersion through a filter, thereby obtaining a colored dispersion having a solid content of 23% by weight.

### Preparation Example 4: Preparation of a Colored Dispersion (D-2)

A colored dispersion having a solid content of 23% by weight was prepared in the same manner as in Preparation Example 3, except that 12 g of carbon black, 53 g of lactam black (Black 582, BASF) as an organic black, and 16 g of C.I. Pigment Blue 15:6 were employed as a colorant (or a pigment).

### EXAMPLES AND COMPARATIVE EXAMPLES: PREPARATION OF COLORED PHOTOSENSITIVE RESIN COMPOSITIONS

The compounds prepared in the Preparation Examples above were used to prepare photosensitive resin compositions in the Examples and the Comparative Examples as below.

The following additional components were used in the Examples and the Comparative Examples.

TABLE 1

| | | | | Solid content |
|---|---|---|---|---|
| Component | | Compound name and/or brand name | Manufacturer | (% by weight) |
| Photopolymerizable | | Dipentaerythritol hexaacrylate (DPHA) | Nippon | 80 |
| compound (B) | | | Kayaku | |
| Photopoly- | C-1 | 1-[9-ethyl-6-(2-methylbenzoyl)-9H-carbazol- | BASF | 100 |
| merization | | 3-yl]-ethanone-1-(O-acetyloxime) (OXE-02) | | |
| Initiator (C) | C-2 | N-1919 | Adeka | 100 |
| | C-3 | (E)-2-(4-styrylphenyl)-4,6-bis(trichloromethyl)- | Tronly | 100 |
| | | 1,3,5-triazine (Triazine-Y) | | |
| | C-4 | Oxime ester fluorene-based compound (SPI-02) | Samyang | 100 |
| | C-5 | Oxime ester fluorene-based compound (SPI-03) | Samyang | 100 |

| | | |
|---|---|---|
| Colorant (D) | D-1 | Colored dispersion of Preparation Example 3 |
| | D-2 | Colored dispersion of Preparation Example 4 |

| Compound derived | Preparation Example 2 | | |
|---|---|---|---|
| from epoxy (E) | | | |
| Surfactant (G) | BYK-307 | BYK | 100 |
| Solvent (H) | Propylene glycol monomethyl ether acetate (PGMEA) | Chemtronics | — |

### Example 1: Preparation of a Colored Photosensitive Resin Composition

100 parts by weight of the compound obtained in Preparation Example 1 as the copolymer (A), 300 parts by weight DPHA as the photopolymerizable compound (B), 2 parts by weight of SPI-02 as the photopolymerization initiator (C-4), 385 parts by weight of the colored dispersion (D-1) prepared in Preparation Example 3 as the colorant, and 1.0 part by weight of the surfactant (G) were mixed, based on the weight of the solid content, followed by an addition of PGMEA as the solvent (H) thereto such that the solid content reached 19% by weight and the total weight was 30 g. Then, the resultant was uniformly mixed for 1 hour to thereby prepare a liquid-phase colored photosensitive resin composition.

### Examples 2 to 5 and Comparative Examples 1 to 6: Preparation of Colored Photosensitive Resin Compositions

Colored photosensitive resin compositions were prepared in the same manner as in Example 1, except that the components of the resin compositions and/or the amounts of the components were changed as shown in the following Table 2.

TABLE 2

| Component | | Comparative Example | | | | | | Example | | | | |
|---|---|---|---|---|---|---|---|---|---|---|---|---|
| (part by weight) | | 1 | 2 | 3 | 4 | 5 | 6 | 1 | 2 | 3 | 4 | 5 |
| Copolymer (A) | | 100 | 100 | 100 | 100 | 100 | 100 | 100 | 100 | 100 | 100 | 100 |
| Compound derived from | | 149 | 173 | 213 | 173 | 0 | 0 | 100 | 0 | 73 | 175 | 0 |
| epoxy (E) | | | | | | | | | | | | |
| Photopolymerizable | | 189 | 208 | 219 | 208 | 54 | 82 | 300 | 100 | 132 | 163 | 72 |
| compound (B) | | | | | | | | | | | | |
| Colorant (D) | D-1 | 311 | 341 | 377 | 341 | — | 129 | 385 | 142 | 216 | 311 | — |
| | D-2 | — | — | — | — | 119 | — | — | — | — | — | 133 |
| Surfactant (G) | | 0.8 | 0.9 | 1.0 | 0.9 | 0.3 | 0.3 | 1.0 | 0.4 | 0.6 | 0.8 | 0.3 |
| Photopolymerization | OXE-2 (C-1) | 4.0 | — | — | — | — | 2.0 | — | — | — | — | — |
| initiator (C) | N-1919 (C-2) | — | 5.0 | 5.0 | — | — | — | — | — | — | — | — |
| | Triazine-Y (C-3) | — | 5.0 | — | — | — | — | — | 2.0 | — | — | — |
| | SPI-02 (C-4) | — | — | — | 5.0 | 3.0 | — | 2.0 | 2.0 | — | 4.0 | 3.0 |
| | SPI-03 (C-5) | — | — | — | — | — | — | — | — | 4.0 | — | — |

| | |
|---|---|
| Solvent (H) | Balance |

Preparation of Light Shielding Spacers and Cured Films

The colored photosensitive resin compositions obtained in the Examples and in Comparative Examples were each coated on a glass substrate using a spin coater and pre-baked at 95° C. for 150 seconds to form a coated film in a thickness of 3.8 μm. A full-tone mask was placed on the coated film thus formed such that an area of 5 cm by 5 cm of the coated film was 100% exposed to light and that the gap with the substrate was maintained at 50 m. Thereafter, the coated film was irradiated with light at an exposure rate of 100 mJ/cm² based on a wavelength of 365 nm for a certain period of time using an aligner (model name: MA6), which emits light having a wavelength of 200 nm to 450 nm. It was then developed at 23° C. with an aqueous solution of potassium hydroxide diluted to a concentration of 0.04% by weight until the unexposed portion was completely washed out. The pattern thus formed was post-baked in an oven at 230° C. for 30 minutes to obtain a light shielding spacer in a thickness of 3.5 μm (±0.1 μm). In addition, the same procedures were carried out without a mask to obtain a cured film in which no pattern was formed.

### Test Example 1: Evaluation of Sensitivity

A black column spacer (BCS) in which the thickness of the spacer was 3.5 μm and the thickness of the light shielding film was 2 μm was prepared using full-tone and half-tone masks having transmittances different from each other instead of the above full-tone mask, which was developed for a developing time ranging from 10 seconds to 20 seconds. The minimum exposure dose at which the spacer pattern was formed was measured.

### Test Example 2: Measurement of Elasticity

A cured film having a total thickness of 3.5 μm (±0.1 μm) upon post-bake and a spacer dot pattern diameter of 35 μm was prepared according to the method for preparing a cured film as described above. The compressive displacement and the elastic recovery rate were measured according to the following measuring conditions using an elasticity instrument (FISCHERSCOPE® HM2000LT, Fisher Technology). A 50 m×50 m planar Vickers indenter in a tetragonal shape was used as an indenter for pressing the pattern. The measurement was carried out by a load-unload method. After a load of 1.96 mN was applied onto the dot pattern using the above-mentioned elasticity instrument, it was defined as an initial condition (H0) for measuring the mechanical properties, that is, the compressive displacement and the elastic recovery rate. Then, the load applied onto each pattern sample was increased at a rate of 5 mN/sec in the thickness direction up to 100 mN and maintained for 5 seconds, and the distance (H1) to which the indenter moved was measured. Upon completion of the holding for 5 seconds, the load was released at a rate of 5 mN/sec in the thickness direction. When the force applied to the dots by the indenter reached 1.96 mN, the force was maintained for 5 seconds. The distance (H2) to which the indenter moved was measured. The elastic recovery rate was calculated according to the following Equation 1.

Elastic recovery rate (%)=[(H1−H2)/(H1−H0)×100] [Equation 1]

### Test Example 3: Measurement of Outgassing During the Process

A substrate having a thickness of 3.0 μm, a width of 0.3 cm, and a length of 0.7 cm was prepared in the same manner as above. Then, the total amount of impurities detected using a pyrolyzer (GC/MS) was measured as the count of outgassing.

### Test Example 4: Evaluation of Surface Characteristics

In order to evaluate whether there existed wrinkles in the BCS of Test Example 1, the surface thereof was photographed with an optical microscope (STM6, Olympus), and the photographs are shown in FIG. 2. Further, if the surface was not smooth or there were wrinkles in the thickness direction, it was evaluated as NG; if the surface was smooth and there is no wrinkle in the thickness direction, it was evaluated as OK. The results are shown in Table 3 below.

### Test Example 5: Evaluation of Step Difference

A BCS was prepared using full-tone and half-tone masks having transmittances different from each other instead of the above full-tone mask at an exposure dose such that a pattern was formed in which the thickness of the spacer was 3.5 m and the thickness of the light shielding film was 2 μm, the image of which was observed with an optical microscope (STM6, Olympus). The results are shown in Table 3 and FIG. 3.

### Test Example 6: Measurement of Optical Density

A cured film having a thickness of 3.5 μm was prepared in the same manner as above. The transmittance at 550 nm of the cured film was measured using an optical density meter (361T manufactured by Xlite), and the optical density based on a thickness of 1 μm was determined.

TABLE 3

| | Comparative Example | | | | | |
|---|---|---|---|---|---|---|
| | 1 | 2 | 3 | 4 | 5 | 6 |
| No. of epoxy groups (mole) | 0.0199 | 0.017 | 0.0158 | 0.0158 | 0.0115 | 0.0123 |
| No. of double bonds (mole) | 0.000502 | 0.000469 | 0.000424 | 0.000424 | 0.00349 | 0.001102 |
| No. of double bond moles/No. | 39.641 | 36.247 | 37.264 | 37.264 | 3.295 | 11.162 |
| of epoxy group moles | | | | | | |
| Sensitivity (mJ/cm²) | 60 | 75 | 70 | 45 | 50 | 60 |
| Elastic recovery rate (100 mN) | 88 | 84 | 84 | 90 | 88 | 88 |
| Optical density (/μm) | 1.2 | 1.2 | 1.2 | 1.2 | 1.2 | 1.2 |
| Outgassing (count) | 9681 | 17197 | 9980 | 8183 | NM | 10732 |
| Surface wrinkles | NG | NG | NG | NG | NM | OK |
| Step formation | ∘ | ∘ | ∘ | ∘ | ND | ∘ |

| | Example | | | | |
|---|---|---|---|---|---|
| | 1 | 2 | 3 | 4 | 5 |
| No. of epoxy groups (mole) | 0.0227 | 0.0162 | 0.0152 | 0.0155 | 0.0131 |
| No. of double bonds (mole) | 0.00068 | 0.00113 | 0.00069 | 0.00051 | 0.00252 |
| No. of double bond moles/No. | 33.382 | 14.336 | 22.029 | 30.392 | 5.198 |
| of epoxy group moles | | | | | |
| Sensitivity (mJ/cm²) | 45 | 45 | 55 | 50 | 50 |
| Elastic recovery rate (100 mN) | 91 | 90 | 90 | 90 | 91 |
| Optical density (/μm) | 1.2 | 1.2 | 1.2 | 1.2 | 1.2 |
| Outgassing (count) | 8425 | 8379 | 8105 | 8027 | 8008 |
| Surface wrinkles | OK | OK | OK | OK | OK |
| Step formation | ∘ | ∘ | ∘ | ∘ | ∘ |

* NM: not measurable;
ND: not developed

As shown in FIGS. 2 and 3 and Table 3, the cured films, e.g., the light shielding spacers (or black column spacers) prepared from the compositions of the Examples, which fall within the scope of the present invention, generated a relatively small amount of outgassing, which may cause a contamination problem, during the process; were excellent overall in terms of sensitivity, elastic recovery rate, and optical density; had no surface wrinkle and irregularity that may be caused by a difference in the height; and had a distinct step difference. In contrast, the cured films prepared from the compositions of the Comparative Examples were poor in most of the physical properties; had a surface that was not smooth and wrinkles and/or irregularities; the step difference was not distinct or cannot be formed; and generated a relatively large amount of outgassing during the process.

### REFERENCE NUMERALS OF THE DRAWINGS

A: thickness of the column spacer part
B: thickness of the black mattress part
C: Critical dimension (CD) of the column spacer part

1. A colored photosensitive resin composition, which comprises:
(A) a copolymer comprising an epoxy group;
(B) a photopolymerizable compound comprising a double bond;
(C) a photopolymerization initiator; and
(D) a colorant,
wherein the molar ratio of the double bonds in the photopolymerizable compound (B) to the epoxy groups in the copolymer (A) satisfies the following relationship:
4≤number of moles of double bonds/number of moles of epoxy groups≤35; and
the photopolymerization initiator (C) comprises an oxime ester fluorene-based initiator of the following Formula 1: 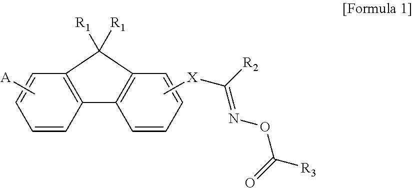
wherein R₁ is each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, or C₁₋₂₀ hydroxyalkoxyalkyl,
R₂ and R₃ are each independently hydrogen, halogen, C₁₋₂₀ alkyl, C₃₋₂₀ cycloalkyl, C₆₋₃₀ aryl, C₇₋₃₀ arylalkyl, C₁₋₂₀ alkoxy, C₁₋₂₀ hydroxyalkyl, C₁₋₂₀ hydroxyalkoxyalkyl, or C₄₋₂₀ heterocycle,
X is a single bond or carbonyl,
A is hydrogen, C₁₋₂₀ alkyl, C₆₋₃₀ aryl, C₁₋₂₀ alkoxy, C₇₋₃₀ arylalkyl, C₁₋₂₀ hydroxyalkyl, C₁₋₂₀ hydroxyalkoxyalkyl, C₃₋₂₀ cycloalkyl, amino, hydroxy, nitro, cyano, or 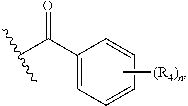
R₄ is R₅, OR₅, SR₅, COR₅, CONR₅R₅, NR₅COR₅, OCOR₅, COOR₅, SCOR₅, OCSR₅, COSR₅, CSOR₅, CN, halogen, or hydroxy,
R₅ is each independently C₁₋₂₀ alkyl, C₆₋₃₀ aryl, C₇₋₃₀ arylalkyl, or C₄₋₂₀ heterocycle,
n is an integer of 0 to 4.

2. The colored photosensitive resin composition of claim 1, wherein R₁ is each independently hydrogen, bromo, chloro, iodo, phenyl, naphthyl, biphenyl, terphenyl, anthryl, indenyl, phenanthryl, methoxy, ethoxy, n-propyloxy, i-propyloxy, n-butoxy, i-butoxy, t-butoxy, hydroxymethyl, hydroxyethyl, hydroxy n-propyl, hydroxy n-butyl, hydroxy i-butyl, hydroxy n-pentyl, hydroxy i-pentyl, hydroxy n-hexyl, hydroxy i-hexyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, hydroxyethoxypentyl, hydroxyethoxyhexyl, methyl, ethyl, n-propyl, i-propyl, n-butyl, i-butyl, t-butyl, n-pentyl, i-pentyl, n-hexyl or i-hexyl;
R₂ and R₃ are each independently hydrogen, bromo, chloro, iodo, methoxy, ethoxy, n-propyloxy, i-propyloxy, n-butoxy, i-butoxy, t-butoxy, hydroxymethyl, hydroxyethyl, hydroxy n-propyl, hydroxy n-butyl, hydroxy i-butyl, hydroxy n-pentyl, hydroxy i-pentyl, hydroxy n-hexyl, hydroxy i-hexyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, hydroxyethoxypentyl, hydroxyethoxyhexyl, methyl, ethyl, n-propyl, i-propyl, n-butyl, i-butyl, t-butyl, n-pentyl, i-pentyl, n-hexyl, i-hexyl, phenyl, naphthyl, biphenyl, terphenyl, anthryl, indenyl, or phenanthryl; and
A is hydrogen, methyl, ethyl, n-propyl, i-propyl, n-butyl, i-butyl, t-butyl, phenyl, naphthyl, biphenyl, terphenyl, anthryl, indenyl, phenanthryl, methoxy, ethoxy, propyloxy, butoxy, hydroxymethyl, hydroxyethyl, hydroxypropyl, hydroxybutyl, hydroxymethoxymethyl, hydroxymethoxyethyl, hydroxymethoxypropyl, hydroxymethoxybutyl, hydroxyethoxymethyl, hydroxyethoxyethyl, hydroxyethoxypropyl, hydroxyethoxybutyl, amino, nitro, cyano, or hydroxy.

3. The colored photosensitive resin composition of claim 1, wherein R₁ is each independently methyl, ethyl, n-propyl, i-propyl, n-butyl, i-butyl, t-butyl, n-pentyl, i-pentyl, n-hexyl, or i-hexyl;
R₂ and R₃ are each independently methyl, ethyl, n-propyl, i-propyl, n-butyl, i-butyl, t-butyl, n-pentyl, i-pentyl, n-hexyl, i-hexyl, phenyl, naphthyl, biphenyl, terphenyl, anthryl, indenyl, or phenanthryl; and
A is nitro, cyano, or hydroxy.

4. The colored photosensitive resin composition of claim 1, wherein the photopolymerization initiator (C) further comprises a triazine-based initiator represented by the following Formula 2: 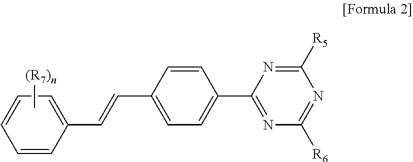
wherein R₅ and R₆ are each independently a halomethyl group,
R₇ is each independently hydrogen, C₁₋₄ alkyl, or C₁₋₄ alkoxy, and
n is an integer of 0 to 3.

5. The colored photosensitive resin composition of claim 1, which further comprises (E) a compound derived from an epoxy resin and having a double bond.

6. The colored photosensitive resin composition of claim 5, wherein the molar ratio of the double bonds in the photopolymerizable compound (B) and in the compound derived from an epoxy resin (E) to the epoxy groups in the copolymer (A) satisfies the following relationship:
4≤number of moles of double bonds/number of moles of epoxy groups≤35.

7. The colored photosensitive resin composition of claim 5, wherein the compound derived from an epoxy resin and having a double bond (E) has a cardo backbone structure.

8. The colored photosensitive resin composition of claim 1, which comprises the photopolymerization initiator (C) in an amount of 0.01 to 10 parts by weight based on 100 parts by weight of the copolymer (A).

9. The colored photosensitive resin composition of claim 1, wherein the colorant is at least one selected from the group consisting of a black colorant and a colorant other than black.

10. The colored photosensitive resin composition of claim 9, wherein the black colorant comprises at least one colorant selected from the group consisting of a black inorganic colorant and a black organic colorant.

11. The colored photosensitive resin composition of claim 9, wherein the colorant other than black comprises at least one colorant selected from the group consisting of a blue colorant and a violet colorant.

12. The colored photosensitive resin composition of claim 11, wherein the colorant comprises 0 to 15% by weight of a black inorganic colorant, 0 to 40% by weight of a black organic colorant, and 0 to 20% by weight of a colorant other than black based on the total weight of the solid content of the colored photosensitive resin composition.

13. The colored photosensitive resin composition of claim 1, wherein the colorant comprises a dispersion resin, and the dispersion resin has an amine value of 3 mg KOH/g or less and comprises 30% by mole or less of a maleimide monomer based on the total number of moles of the constituent units.

14. A light shielding spacer produced from the colored photosensitive resin composition of claim 1.

15. The light shielding spacer of claim 14, which has an optical density of 0.5 to 2.0/μm.

16. The light shielding spacer of claim 14, which has an elastic recovery rate of 90% or more.
